(19) United States
(12) Patent Application Publication
(10) Pub. No.: US 2025/0357721 A1
(43) Pub. Date: Nov. 20, 2025

(54) LASER SYSTEM AND ELECTRONIC DEVICE MANUFACTURING METHOD

(71) Applicants: Gigaphoton Inc., Oyama-shi (JP); Inter-University Research Institute Corporation, National Institutes of Natural Sciences, Tokyo (JP)

(72) Inventors: Yuki TAMARU, Oyama-shi (JP); Taisuke MIURA, Oyama-shi (JP); Ryo YASUHARA, Toki-shi (JP)

(73) Assignees: Gigaphoton Inc., Oyama-shi (JP); Inter-University Research Institute Corporation, National Institutes of Natural Sciences, Tokyo (JP)

(21) Appl. No.: 19/289,812

(22) Filed: Aug. 4, 2025

Related U.S. Application Data
(63) Continuation of application No. PCT/JP2023/012679, filed on Mar. 28, 2023.

(51) Int. Cl. H01S 3/10; G02F 1/09; G03F 7/00; G03F 7/20; H01L 21/268; H01S 3/23

(52) U.S. Cl. CPC H01S 3/10061; G02F 1/09; G03F 7/2002; G03F 7/70025; G03F 7/70041; G03F 7/7055; H01S 3/2383; H01L 21/268

(57) ABSTRACT

A laser system includes a laser oscillator system outputting first pulsed laser light in a first polarization direction and second pulsed laser light in a second polarization direction rotated by 45 degrees from the first polarization direction in a first rotation direction, a beam combiner coupling the first and second pulsed laser light, a power supply, and a processor, the beam combiner including a first polarizer, a first Faraday rotator rotating the polarization direction of the first pulsed laser light transmitted through the first polarizer by 45 degrees in a direction opposite to the first rotation direction, a second polarizer transmitting the first pulsed laser light transmitted through the first Faraday rotator and reflecting the second pulsed laser light, and a multi-pass Faraday mirror reflecting the first and second pulsed laser light toward the second polarizer. The multi-pass Faraday mirror includes a first Faraday material, an electromagnet, and a plurality of reflective mirrors, and the processor controls a current flowing to the electromagnet via the power supply such that no current is caused to flow when the first pulsed laser light is transmitted and a current is caused to flow to rotate a polarization direction of the second pulsed laser light by 90 degrees when the second pulsed laser light is transmitted through the first Faraday material.

### CROSS-REFERENCE TO RELATED APPLICATIONS

The present application is a continuation application of International Application No. PCT/JP2023/012679, filed on Mar. 28, 2023, the entire contents of which are hereby incorporated by reference.

### BACKGROUND

### 1. Technical Field

The present disclosure relates to a laser system and an electronic device manufacturing method.

### 2. Related Art

In recent years, an improvement in resolutions of semiconductor exposure apparatuses has been desired with miniaturization and high integration of semiconductor integrated circuits. For this purpose, an exposure light source that outputs light having a shorter wavelength has been developed. For example, a KrF excimer laser apparatus that outputs laser light having a wavelength of about 248 nm and an ArF excimer laser apparatus that outputs laser light having a wavelength of about 193 nm are used as gas laser apparatuses for exposure.

Spectral linewidths of spontaneous oscillation light of the KrF excimer laser apparatus and the ArF excimer laser apparatus are as wide as 350 pm to 400 pm. Therefore, if a projection lens is formed of a material that transmits ultraviolet light such as KrF laser light and ArF laser light, chromatic aberration may occur. As a result, resolving power potentially decreases. Thus, the spectral linewidths of the laser light output from the gas laser apparatuses need to be narrowed to an extent that the chromatic aberration is ignorable. For this purpose, a line narrowing module (LNM) including a line narrowing element (etalon, grating, and the like) may be included in a laser resonator of such a gas laser apparatuses to narrow the spectral linewidth. Hereinafter, a gas laser apparatus with a narrowed spectral linewidth will be referred to as a line narrowing gas laser apparatus.

### LIST OF DOCUMENTS

### Patent Documents

Patent Document 1: International Publication No. WO 2021/108054
Patent Document 2: US Patent Application Publication No. 2005/146769

### SUMMARY

A laser system according to an aspect of the present disclosure includes a laser oscillator system configured to output first pulsed laser light in a first polarization direction and second pulsed laser light in a second polarization direction, which is obtained by rotating the first polarization direction by 45 degrees in a first rotation direction, a beam combiner configured to couple the first pulsed laser light and the second pulsed laser light such that the first pulsed laser light and the second pulsed laser light are caused to propagate in a common direction, the beam combiner including a first polarizer that transmits the first pulsed laser light, a first Faraday rotator that rotates a polarization direction of the first pulsed laser light transmitted through the first polarizer by 45 degrees in a second rotation direction that is a direction opposite to the first rotation direction, a second polarizer that transmits the first pulsed laser light transmitted through the first Faraday rotator and reflects the second pulsed laser light, and a multi-pass Faraday mirror that reflects the first pulsed laser light transmitted through the second polarizer and the second pulsed laser light reflected by the second polarizer towards the second polarizer, the multi-pass Faraday mirror including a first Faraday material through which the first pulsed laser light and the second pulsed laser light are transmitted, an electromagnet that applies a magnetic field to the first Faraday material, and a plurality of reflective mirrors that cause the first pulsed laser light and the second pulsed laser light transmitted through the first Faraday material to turn back toward the first Faraday material, a power supply configured to cause a current to flow to the electromagnet, and a processor configured to control the current flowing to the electromagnet via the power supply such that no current is caused to flow to the electromagnet when the first pulsed laser light is transmitted through the first Faraday material while a current is caused to flow to the electromagnet to rotate a polarization direction of the second pulsed laser light by 90 degrees when the second pulsed laser light is transmitted through the first Faraday material.

An electronic device manufacturing method according to another aspect of the present disclosure includes generating laser light with a laser system, the laser system including a laser oscillator system configured to output first pulsed laser light in a first polarization direction and second pulsed laser light in a second polarization direction, which is obtained by rotating the first polarization direction by 45 degrees in a first rotation direction, a beam combiner configured to couple the first pulsed laser light and the second pulsed laser light such that the first pulsed laser light and the second pulsed laser light are caused to propagate in a common direction, the beam combiner including a first polarizer that transmits the first pulsed laser light, a first Faraday rotator that rotates a polarization direction of the first pulsed laser light transmitted through the first polarizer by 45 degrees in a second rotation direction that is a direction opposite to the first rotation direction, a second polarizer that transmits the first pulsed laser light transmitted through the first Faraday rotator and reflects the second pulsed laser light, and a multi-pass Faraday mirror that reflects the first pulsed laser light transmitted through the second polarizer and the second pulsed laser light reflected by the second polarizer towards the second polarizer, the multi-pass Faraday mirror including a first Faraday material through which the first pulsed laser light and the second pulsed laser light are transmitted, an electromagnet that applies a magnetic field to the first Faraday material, and a plurality of reflective mirrors that cause the first pulsed laser light and the second pulsed laser light transmitted through the first Faraday material to turn back toward the first Faraday material, a power supply configured to cause a current to flow to the electromagnet, and a processor configured to control the current flowing to the electromagnet via the power supply such that no current is caused to flow to the electromagnet when the first pulsed laser light is transmitted through the first Faraday material while a current is caused to flow to the electromagnet via the power supply to rotate a polarization direction of the second pulsed laser light by 90 degrees when the second pulsed laser light is transmitted through the first Faraday material, outputting the laser light to an exposure apparatus, and exposing a photosensitive substrate to the laser light within the exposure apparatus to manufacture an electronic device.

### BRIEF DESCRIPTION OF THE DRAWINGS

Some embodiments of the present disclosure will be described below just as examples with reference to the accompanying drawings.

FIG. 1 schematically illustrates a configuration of a laser system according to a comparative example.

FIG. 2 is an explanatory diagram illustrating a state where a mirror of a beam combiner according to the comparative example is disposed at a first position.

FIG. 3 is an explanatory diagram illustrating a state where the mirror of the beam combiner according to the comparative example is disposed at a second position.

FIG. 4 schematically illustrates a configuration of a laser system according to a first embodiment.

FIG. 5 schematically illustrates a configuration of a beam combiner used in the first embodiment.

FIG. 6 is an explanatory diagram illustrating how first pulsed laser light output from a first laser oscillator propagates.

FIG. 7 is an explanatory diagram illustrating how second pulsed laser light output from a second laser oscillator propagates.

FIG. 8 schematically illustrates a configuration of a multi-pass Faraday mirror according to a modification of the first embodiment.

FIG. 9 schematically illustrates a configuration of a laser system according to a second embodiment.

FIG. 10 is an explanatory diagram illustrating how second pulsed laser light output from a third laser oscillator propagates.

FIG. 11 schematically illustrates a configuration of a laser system according to a third embodiment.

FIG. 12 is an explanatory diagram illustrating how first pulsed laser light output from a first amplifier propagates.

FIG. 13 is an explanatory diagram illustrating how second pulsed laser light output from a second amplifier propagates.

FIG. 14 schematically illustrates a configuration of an exposure apparatus.

### DESCRIPTION OF EMBODIMENTS

### Contents

1. Explanation of terms
   1.1 Faraday Material
   1.2 Multi-pass Faraday Mirror
2. Overview of laser system according to comparative example
   2.1 Configuration
   2.2 Operation
   2.3 Problem
3. First Embodiment
   3.1 Configuration
   3.2 Operation
   3.3 Effect
   3.4 Modification
      3.4.1 Configuration
      3.4.2 Operation
      3.4.3 Effect
4. Second Embodiment
   4.1 Configuration
   4.2 Operation
   4.3 Effect
5. Third Embodiment
   5.1 Configuration
   5.2 Operation
   5.3 Effect
6. Concerning electronic device manufacturing method
7. Others

Embodiments of the present disclosure will be described below in detail with reference to the drawings. The embodiments described below are some examples of the present disclosure, and do not limit the contents of the present disclosure. Not all configurations and operations described in each embodiment are necessarily essential as configurations and operations of the present disclosure. Components identical to each other will be denoted by an identical reference sign, and duplicate description thereof will be omitted.

### 1. Explanation of Terms

### 1.1 Faraday Material

A Faraday material refers to a material that causes a Faraday effect that is a magneto-optical effect by a magnetic field being applied from outside. Although the Faraday effect occurs in any material, it refers to a material from which the Faraday effect is obtained at an ultraviolet wavelength from 150 nm to 380 nm in the present specification. In the deep ultraviolet region, candidate materials for the Faraday material include calcium fluoride (CaF₂), magnesium fluoride (MgF₂), and synthetic quartz.

### 1.2 Multi-Pass Faraday Mirror

A multi-pass Faraday mirror is configured of a Faraday material, an electromagnet that applies a magnetic field to the Faraday material, and a plurality of reflective mirrors that cause light that has been transmitted through the Faraday material to turn back toward the Faraday material. The plurality reflective mirrors are disposed such that an optical axis of light incident on the multi-pass Faraday mirror and an optical axis of light output from the multi-pass Faraday mirror become the same.

The light incident on the multi-pass Faraday mirror is transmitted through the Faraday material an even number of times, and the polarization direction is rotated by a Faraday effect by the electromagnet applying a magnetic field to the Faraday material when the light is transmitted therethrough. The magnetic field applied from the electromagnet can be reduced by causing the light to be transmitted to the Faraday material a plurality of times. Additionally, the size of the Faraday material can be reduced. Note that the reflective mirrors may be reflective coatings. The reflective coatings that serve as the reflective mirrors are included in the concept of “reflective mirrors”.

### 2. Overview of Laser System According to Comparative Example

### 2.1 Configuration

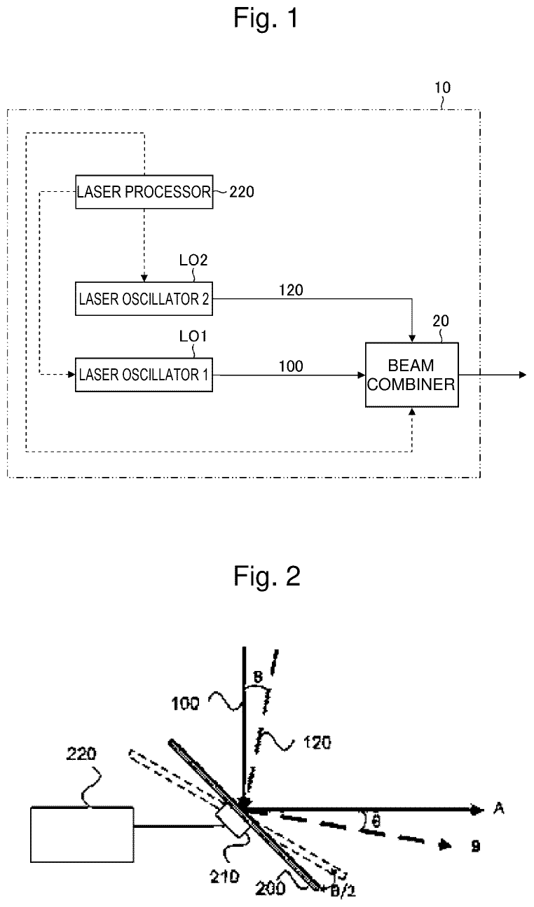

FIG. 1 is a configuration diagram schematically illustrating a configuration of a laser system 10 according to a comparative example. The comparative example of the present disclosure is a form that the applicant recognizes as known only by the applicant, but is not a publicly known example that is recognized by the applicant. The laser system 10 includes a first laser oscillator LO1, a second laser oscillator LO2, a beam combiner 20, and a laser processor 220.

The first laser oscillator LO1 outputs first pulsed laser light 100. The second laser oscillator LO2 outputs second pulsed laser light 120.

The beam combiner 20 couples the first pulsed laser light 100 and the second pulsed laser light 120 such that they propagate in a common direction.

The laser processor 220 causes the first pulsed laser light 100 and the second pulsed laser light 120 to be alternately output at the same repetition frequency, allowing the laser system 10 to output pulsed laser light at a repetition frequency that is twice the repetition frequency of the first pulsed laser light 100 and the second pulsed laser light 120. For example, when the repetition frequency of the first pulsed laser light 100 and the second pulsed laser light 120 is 6 kHz, the laser system 10 can output pulsed laser light at a repetition frequency of 12 kHz.

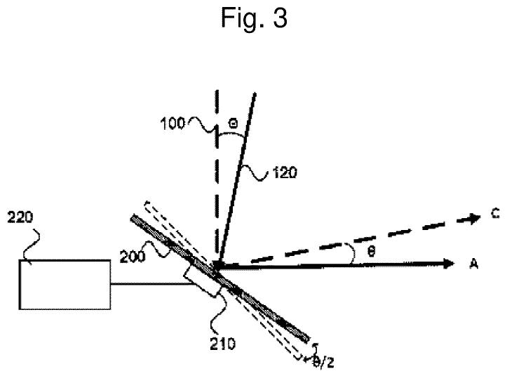

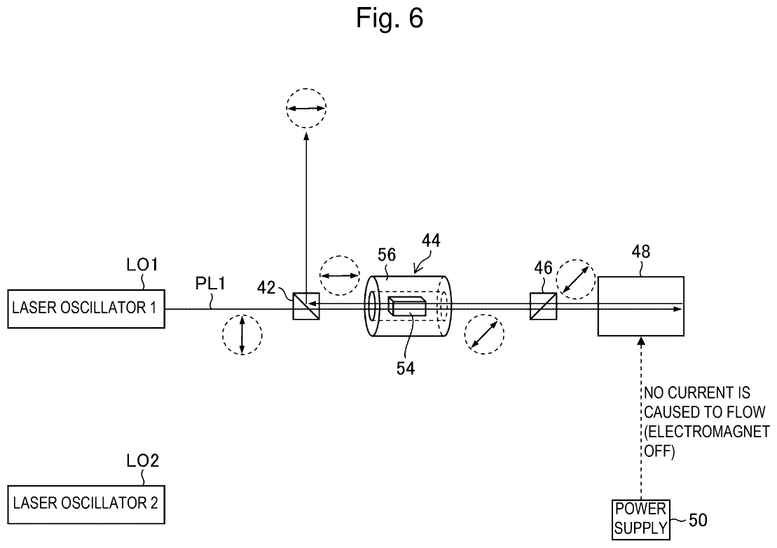

FIGS. 2 and 3 illustrate a configuration of the beam combiner 20. Note that FIGS. 2 and 3 are cited from FIGS. 6A and 6B of Patent Document 1.

The beam combiner 20 includes a mirror 200 and an actuator 210. In FIGS. 2 and 3, the solid arrows indicate propagation of active pulsed laser light, while the dashed arrows indicate propagation of pulsed laser light when the mirror 200 is located at other positions indicated by the dashed lines. The first pulsed laser light 100 and the second pulsed laser light 120 are incident on the beam combiner 20 at an angle θ between their optical axes. The direction A is a direction in which the pulsed laser light is output from the laser system 10.

### 2.2 Operation

When the laser system 10 outputs the first pulsed laser light 100 output from the first laser oscillator LO1, the laser processor 220 transmits a control signal to the actuator 210 such that the position of the mirror 200 of the beam combiner 20 is located at a first position indicated by the solid line in FIG. 2. When the laser system 10 outputs the second pulsed laser light 120 output from the second laser oscillator LO2, the laser processor 220 transmits a control signal to the actuator 210 such that the position of the mirror 200 of the beam combiner 20 is located at a second position indicated by the solid line in FIG. 3.

The angle difference between the first position and the second position of the mirror 200 is 0/2. The laser processor 220 outputs pulsed laser light at the repetition frequency of the first pulsed laser light 100 and the second pulsed laser light 120 from the laser system 10 by alternately switching the position of the mirror 200 to the first position or the second position in accordance with the pulsed laser light incident on the beam combiner 20.

### 2.3 Problem

Although the beam combiner 20 includes a movable portion that switches the position of the mirror 200 with the actuator 210, it is difficult to switch the position with satisfactory reproducibility at a high repetition frequency such as 12 kHz. Therefore, position reproducibility of the pulsed laser light output from the laser system 10 is poor.

It is desirable to improve the beam combiner 20 to cause the two pulsed laser light beams to propagate in a common direction and to realize a laser system in which the position of pulsed laser light to be output is less likely to fluctuate (with excellent position reproducibility).

### 3. First Embodiment

### 3.1 Configuration

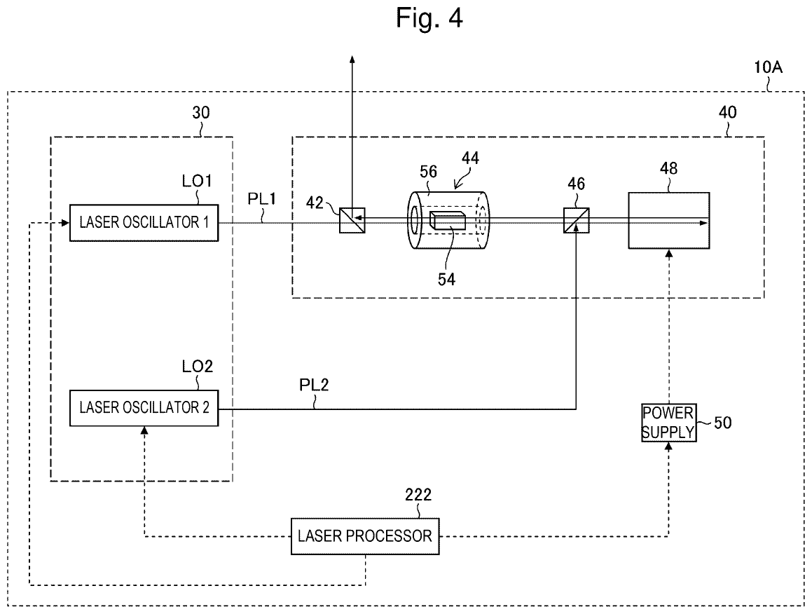

FIG. 4 schematically illustrates a configuration of a laser system 10A according to a first embodiment. The laser system 10A includes a laser oscillator system 30, a beam combiner 40, and a laser processor 222.

The laser oscillator system 30 includes a first laser oscillator LO1 and a second laser oscillator LO2. Note that in the drawing, the notation “laser oscillator 1” represents a first laser oscillator LO1 and the notation “laser oscillator 2” represents a second laser oscillator LO2. The first laser oscillator LO1 outputs first pulsed laser light PL1 in a first polarization direction at an ultraviolet wavelength which is 150 nm to 380 nm. The first laser oscillator LO1 may be a KrF excimer laser or an ArF excimer laser. The spectral linewidth of the first pulsed laser light PL1 may be narrowed to 1 pm or less.

The second laser oscillator LO2 outputs second pulsed laser light PL2 in a second polarization direction, which is obtained by rotating the first polarization direction by 45 degrees counterclockwise, at an ultraviolet wavelength which is 150 nm to 380 nm. The counterclockwise direction is an example of the “first rotation direction” in the present disclosure. The second laser oscillator LO2 may be a KrF excimer laser or an ArF excimer laser. The spectral linewidth of the second pulsed laser light PL2 may be narrowed to 1 pm or less.

The laser processor 222 functions as a control device of the laser system 10A. The laser processor 222 is a processing device including a storage device that stores a control program and a central processing unit (CPU) that executes the control program. The laser processor 222 is specially configured or programmed to execute various kinds of processing included in the present disclosure. The storage device is a non-transitory computer-readable medium as a tangible entity and includes, for example, a memory that is a main storage device and a storage that is an auxiliary storage device. The computer-readable medium may be, for example, a semiconductor memory, a hard disk drive (HDD) device, a solid-state drive (SSD) device, or a combination of some of them.

The beam combiner 40 includes a first polarizer 42, a Faraday rotator 44, a second polarizer 46, and a multi-pass Faraday mirror 48. In addition, the laser system 10A includes a power supply 50 that supplies a current to the multi-pass Faraday mirror 48. The first laser oscillator LO1, the second laser oscillator LO2, and the power supply 50 are each controlled by the laser processor 222.

The first polarizer 42 is disposed to allow the first pulsed laser light PL1 to be transmitted therethrough. The first polarizer 42 may be, for example, a polarizing prism or a thin film polarizer.

The Faraday rotator 44 is disposed to allow the first pulsed laser light PL1, which has been transmitted through the first polarizer 42, to be transmitted therethrough. The Faraday rotator 44 is configured of a Faraday material 54 and a permanent magnet 56 that cause the polarization direction of the first pulsed laser light PL1 to rotate by 45 degrees clockwise when viewed in the direction in which the first pulsed laser light PL1 travels. The clockwise direction is an example of the “second rotation direction” in the present disclosure. The Faraday material 54 may be, for example, CaF₂, MgF₂, or synthetic quartz. The permanent magnet 56 applies a magnetic field to the Faraday material 54. The Faraday rotator 44 is an example of the “first Faraday rotator” in the present disclosure. The Faraday material 54 is an example of the “second Faraday material” in the present disclosure, and the permanent magnet 56 is an example of the “first permanent magnet” in the present disclosure.

The second polarizer 46 is disposed to allow the first pulsed laser light PL1, which has been transmitted through the Faraday rotator 44, to be transmitted therethrough and to reflect the second pulsed laser light PL2. The second polarizer 46 may be, for example, a polarizing prism or a thin film polarizer.

The multi-pass Faraday mirror 48 is disposed to allow the first pulsed laser light PL1, which has been transmitted through the second polarizer 46, to be incident thereon.

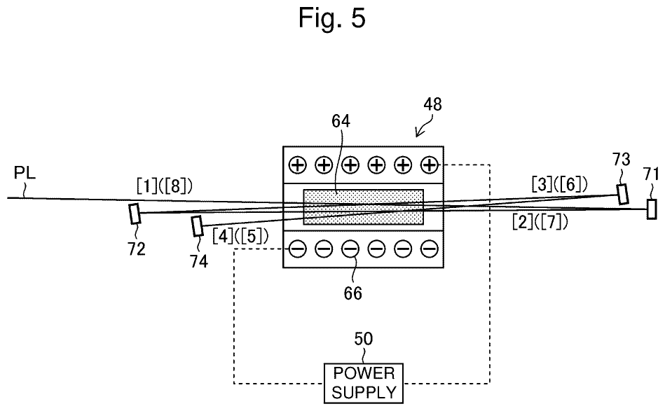

A configuration diagram of the multi-pass Faraday mirror 48 is illustrated in FIG. 5. The multi-pass Faraday mirror 48 includes a Faraday material 64 that causes the polarization direction of the pulsed laser light PL to rotate by 90 degrees clockwise when viewed in the direction in which the pulsed laser light PL travels, a coil 66 that configures an electromagnet, a high reflective mirror 71, a high reflective mirror 72, a high reflective mirror 73, and a high reflective mirror 74.

The Faraday material 64 may be, for example, CaF₂, MgF₂, or synthetic quartz. The Faraday material 64 is an example of the “first Faraday material” in the present disclosure.

The high reflective mirrors 71 to 74 are disposed such that the pulsed laser light PL incident on the multi-pass Faraday mirror 48 is reflected by the high reflective mirror 71, the high reflective mirror 72, the high reflective mirror 73, and the high reflective mirror 74, and is further reflected by the high reflective mirror 73, the high reflective mirror 72, and the high reflective mirror 71, and are then caused to outgo coaxially with the incident pulsed laser light PL.

Note that although FIG. 5 illustrates an example in which the pulsed laser light PL passes through the Faraday material 64 eight times (8 passes), the number of passes may be any even number of 4 or more. The pulsed laser light PL may be the first pulsed laser light PL1 or may be the second pulsed laser light PL2. The high reflective mirrors 71 to 74 are an example of “the plurality of reflective mirrors” in the present disclosure.

The power supply 50 is connected to the coil 66. A magnetic field is applied to the Faraday material 64 by a current flowing from the power supply 50 to the coil 66.

### 3.2 Operation

The laser processor 222 causes the laser oscillator system 30 to alternately output the first pulsed laser light PL1 and the second pulsed laser light PL2 at the same repetition frequency.

FIG. 6 illustrates how the first pulsed laser light PL1 output from the first laser oscillator LO1 propagates. The first pulsed laser light PL1 in the first polarization direction output from the first laser oscillator LO1 is transmitted through the first polarizer 42. Then, the polarization direction rotates by 45 degrees clockwise when the first pulsed laser light PL1 is transmitted through the Faraday rotator 44 to become a third polarization direction. Note that the double-headed arrow illustrated in each dashed-line circle in the drawing represents the direction of the polarization plane, in other words, the polarization direction of the pulsed laser light PL when the line of sight is caused to follow the direction in which the pulsed laser light PL travels. The first pulsed laser light PL1 that has been transmitted through the Faraday rotator 44 is transmitted through the second polarizer 46. The first pulsed laser light PL1 that has been transmitted through the second polarizer 46 is incident on the multi-pass Faraday mirror 48.

The first pulsed laser light PL1 incident on the multi-pass Faraday mirror 48 passes through the Faraday material 64 eight times and is then reflected toward the second polarizer 46. At this time, the laser processor 222 does not cause a current to flow through the coil 66 via the power supply 50. In other words, the electromagnet is OFF. In this case, the polarization direction of the first pulsed laser light PL1 does not rotate when the first pulsed laser light PL1 is transmitted through the multi-pass Faraday mirror 48. Therefore, the polarization direction of the first pulsed laser light PL1 output from the multi-pass Faraday mirror 48 remains the third polarization direction.

The first pulsed laser light PL1 in the third polarization direction reflected by the multi-pass Faraday mirror 48 is transmitted through the second polarizer 46, and its polarization direction rotates by 45 degrees clockwise at the Faraday rotator 44 to become the fourth polarization direction. The first pulsed laser light PL1 in the fourth polarization direction is reflected by the first polarizer 42 and is then output from the laser system 10A.

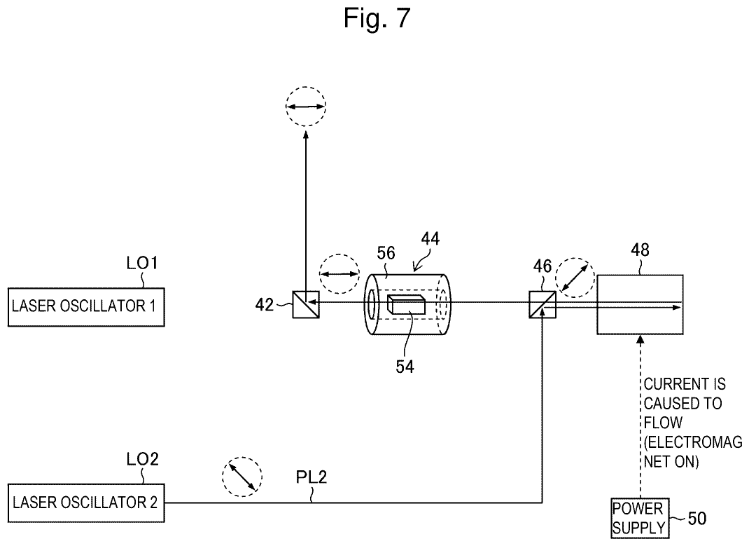

FIG. 7 illustrates how the second pulsed laser light PL2 output from the second laser oscillator LO2 propagates. The second pulsed laser light PL2 in the second polarization direction output from the second laser oscillator LO2 is reflected by the second polarizer 46. Then, the second pulsed laser light PL2 is incident on the multi-pass Faraday mirror 48.

The second pulsed laser light PL2 incident on the multi-pass Faraday mirror 48 passes through the Faraday material 64 eight times and is then reflected toward the second polarizer 46. At this time, the laser processor 222 causes a current to flow through the coil 66 via the power supply 50. In other words, the electromagnet is ON. The magnetic field generated by the electromagnet can be reduced by the second pulsed laser light PL2 passing through the Faraday material 64 eight times. Therefore, the electromagnet can be miniaturized, and the current caused to flow through the coil 66 can be reduced.

The intensity of the magnetic field generated by the electromagnet ranges from 0.005 T to 1.0 T. When the second pulsed laser light PL2 is transmitted through the multi-pass Faraday mirror 48, the polarization direction rotates by 90 degrees clockwise. Therefore, the polarization direction of the second pulsed laser light PL2 reflected by the multi-pass Faraday mirror 48 becomes the third polarization direction.

The second pulsed laser light PL2 in the third polarization direction reflected by the multi-pass Faraday mirror 48 is transmitted through the second polarizer 46, and the polarization direction rotates by 45 degrees clockwise at the Faraday rotator 44 to become the fourth polarization direction. The second pulsed laser light PL2 in the fourth polarization direction is reflected by the first polarizer 42 and is then output from the laser system 10A.

The laser processor 222 turns off the electromagnet when the first pulsed laser light PL1 is incident on the multi-pass Faraday mirror 48, and turns on the electromagnet when the second pulsed laser light PL2 is incident on the multi-pass Faraday mirror 48. As a result, the first pulsed laser light PL1 in the first polarization direction and the second pulsed laser light PL2 in the second polarization direction output from the laser oscillator system 30 are coupled by the beam combiner 40 such that they propagate in a common direction.

The coupled first pulsed laser light PL1 and second pulsed laser light PL2 in the fourth polarization direction are output alternately from the laser system 10A.

The beam combiner 40 still functions even if both the clockwise and counterclockwise directions in the embodiment are opposite directions. However, the polarization direction of the light transmitted through the second polarizer 46 in this case is 90 degrees different from that in the above description.

### 3.3 Effect

With the laser system 10A according to the first embodiment, the following effects can be obtained.

[1] The beam combiner 40 has no movable portions including the actuator 210 illustrated in FIGS. 2 and 3, resulting in high positional reproducibility of the pulsed laser light PL (the first pulsed laser light PL1 and the second pulsed laser light PL2) output from the laser system 10A.

[2] The electromagnet can be miniaturized, and the current caused to flow through the coil 66 can be reduced by causing the multi-pass Faraday mirror 48 to multi-pass the pulsed laser light.

[3] It is possible to output the pulsed laser light PL in the same polarization direction from the laser system 10A.

### 3.4 Modification

### 3.4.1 Configuration

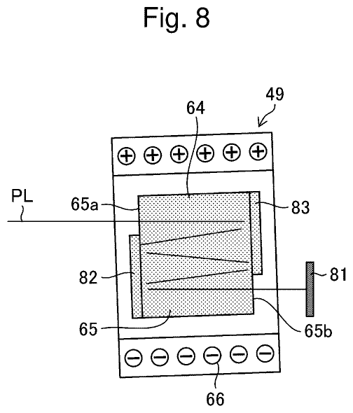

FIG. 8 illustrates a configuration of a multi-pass Faraday mirror 49 according to a modification of the first embodiment. Instead of the multi-pass Faraday mirror 48 illustrated in FIG. 5, the multi-pass Faraday mirror 49 illustrated in FIG. 8 can be used.

The multi-pass Faraday mirror 49 includes a Faraday material 65, a high reflective mirror 81, and a coil 66 that configures an electromagnet. In the Faraday material 65, high reflective coatings 82 and 83 are applied to portions of a first surface 65a that is a surface on which pulsed laser light PL incident and a second surface 65b that is a surface from which the pulsed laser light PL is output toward the high reflective mirror 81.

### 3.4.2 Operation

The pulsed laser light PL incident on the multi-pass Faraday mirror 49 is incident on the Faraday material 65 from a portion of the first surface 65a with no high reflective coating 82 applied thereto. Then, the pulsed laser light PL is reflected by the high reflective coating 83 and the high reflective coating 82 and is then output from a portion of the second surface 65b with no high reflective coating 83 applied thereto.

The pulsed laser light PL output from the second surface 65b of the Faraday material 65 is reflected by the high reflective mirror 81 and then returns to the Faraday material 65.

The pulsed laser light PL reflected by the high reflective mirror 81 is incident on the Faraday material 65 from the portion of the second surface 65b with no high reflective coating 83 applied thereto, is reflected by the high reflective coating 82 and the high reflective coating 83, and is then output from the portion of the first surface 65a with no high reflective coating 82 applied thereto. The reflection at each of the high reflective coating 82 and the high reflective coating 83 is preferably achieved twice or more. In other words, it is desirable for the pulsed laser light PL to pass through the Faraday material 65 four times or more. The high reflective mirror 81 and the high reflective coatings 82 and 83 are examples of the “plurality of reflective mirrors” in the present disclosure.

When the laser processor 222 causes a current to flow through the coil 66 via the power supply 50, that is, when the electromagnet is ON, the polarization direction of the pulsed laser light PL rotates by 90 degrees clockwise when the pulsed laser light PL is transmitted through the multi-pass Faraday mirror 49. The operation of controlling the current (the current of the electromagnet) to be caused to flow through the coil 66 via the power supply 50 and switching ON/OFF of the electromagnet when each of the first pulsed laser light PL1 and the second pulsed laser light PL2 is transmitted through the Faraday material 65 is similar to that in the first embodiment.

### 3.4.3 Effect

With the laser system 10A including the multi-pass Faraday mirror 49 according to the modification, the same effect as that in the first embodiment is obtained. The multi-pass Faraday mirror 49 according to the modification can reduce the number of high reflective mirrors as compared with the multi-pass Faraday mirror 48 according to the first embodiment and brings about further improved position reproducibility as compared with the first embodiment.

### 4. Second Embodiment

### 4.1 Configuration

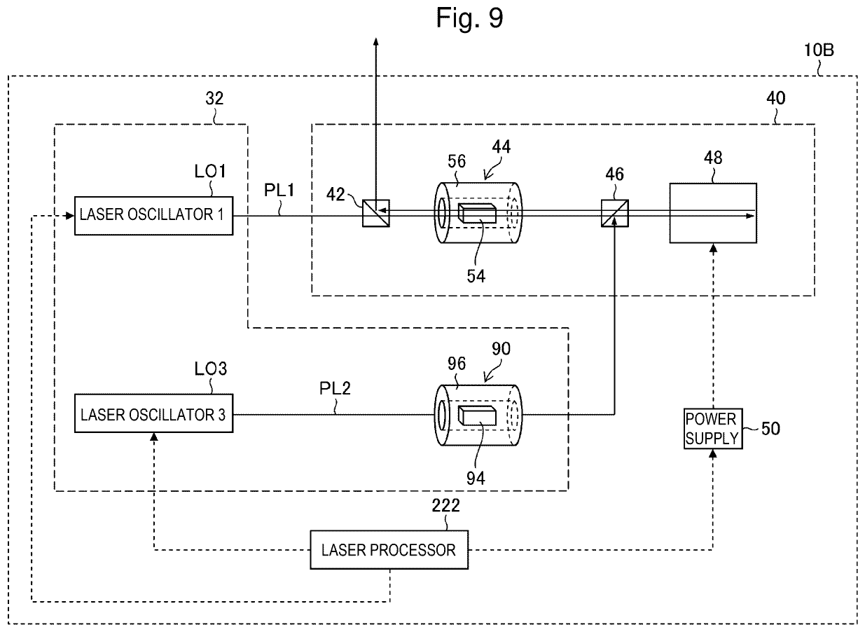

FIG. 9 schematically illustrates a configuration of a laser system 10B according to a second embodiment. Differences of the laser system 10B from the laser system 10A illustrated in FIG. 4 will be described. The laser system 10B includes a laser oscillator system 32 instead of the laser oscillator system 30 illustrated in FIG. 4. The laser oscillator system 32 includes a third laser oscillator LO3 instead of the second laser oscillator LO2 illustrated in FIG. 4 and a Faraday rotator 90. Note that the notation “laser oscillator 3” in the drawing represents the third laser oscillator LO3.

The third laser oscillator LO3 outputs second pulsed laser light PL2 in a first polarization direction at an ultraviolet wavelength of 150 nm to 380 nm. The third laser oscillator LO3 may be a KrF excimer laser or an ArF excimer laser. In addition, the spectral linewidth of the second pulsed laser light PL2 output from the third laser oscillator LO3 may be narrowed to 1 pm or less.

The Faraday rotator 90 is configured of a Faraday material 94 and a permanent magnet 96 that causes the polarization direction of the second pulsed laser light PL2 to rotate by 45 degrees counterclockwise when viewed in a direction in which the second pulsed laser light PL2 travels. The Faraday material 94 may be, for example, CaF₂, MgF₂, or synthetic quartz. Instead of the Faraday rotator 90, a wavelength plate that causes the polarization direction of the second pulsed laser light PL2 to rotate by 45 degrees counterclockwise may be adopted. The other configurations are the same as the configurations illustrated in FIG. 4.

The Faraday rotator 90 is an example of the “second Faraday rotator” in the present disclosure. The Faraday material 94 is an example of the “third Faraday material” in the present disclosure, and the permanent magnet 96 is an example of the “second permanent magnet” in the present disclosure.

### 4.2 Operation

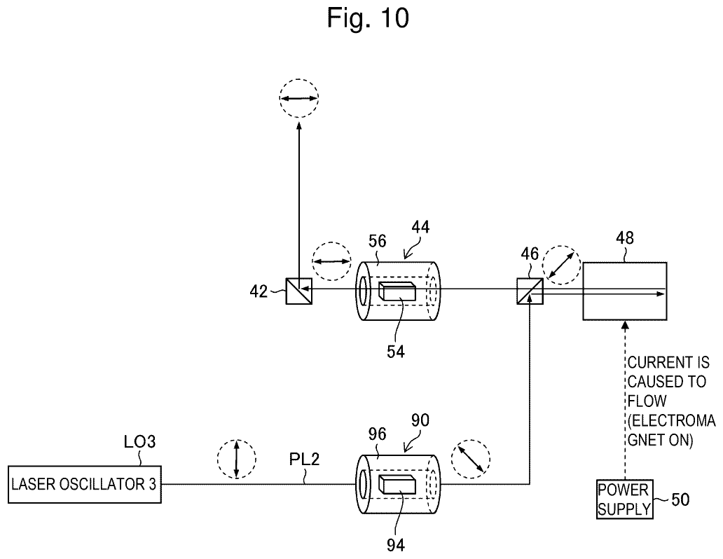

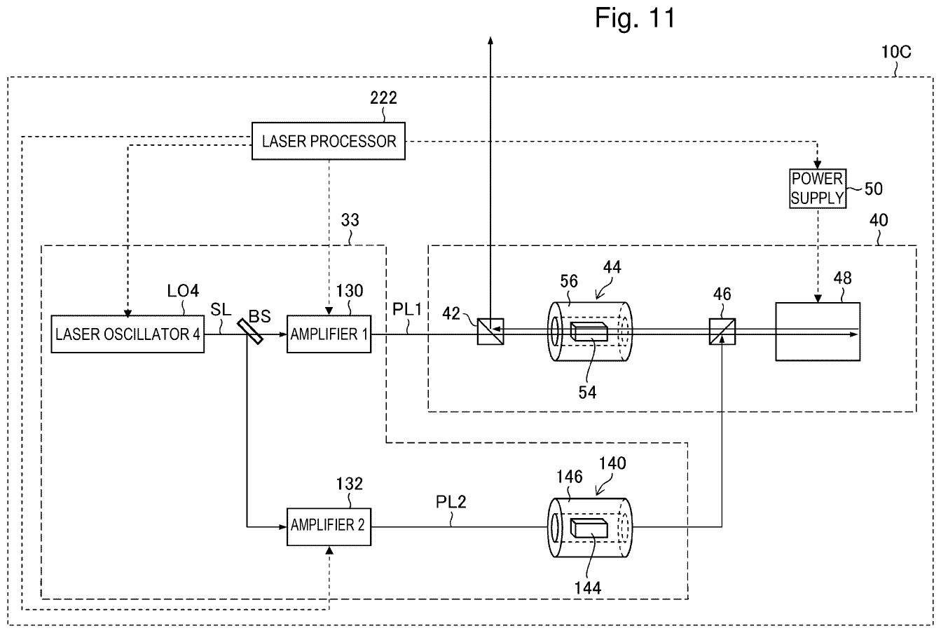

A laser processor 222 causes first pulsed laser light PL1 and the second pulsed laser light PL2 to be alternately output at the same repetition frequency. FIG. 10 illustrates how the second pulsed laser light PL2 output from the third laser oscillator LO3 propagates.

The second pulsed laser light PL2 output from the third laser oscillator LO3 is transmitted through the Faraday rotator 90. At this time, the polarization direction of the second pulsed laser light PL2 is rotated by 45 degrees counterclockwise to become a second polarization direction. The second pulsed laser light PL2 that has been transmitted through the Faraday rotator 90 is reflected by a second polarizer 46 and is then incident on a multi-pass Faraday mirror 48. The subsequent propagation is similar to that in the first embodiment.

Also, propagation of the first pulsed laser light PL1 output from the first laser oscillator LO1 is similar to that in the first embodiment, and control of a current to be caused to flow to an electromagnet via a power supply 50 and the other operations are also similar to those in the first embodiment.

4.3 Effect With the laser system 10B according to the second embodiment, the same effect as that in the first embodiment is obtained. In the laser system 10B, the polarization directions of the first pulsed laser light PL1 output from the first laser oscillator LO1 and the second pulsed laser light PL2 output from the third laser oscillator LO3 can be made the same.

### 5. Third Embodiment

### 5.1 Configuration

FIG. 11 illustrates a configuration of a laser system 10C according to a third embodiment. Differences of the laser system 10C from the laser system 10A illustrated in FIG. 4 will be described. The laser system 10C includes a laser oscillator system 33 instead of the laser oscillator system 30 illustrated in FIG. 4. The laser oscillator system 33 includes a fourth laser oscillator LO4, a beam splitter BS, a first amplifier 130, a second amplifier 132, and a Faraday rotator 140. Note that the notation “laser oscillator 4” in the drawing represents the fourth laser oscillator LO4. Also, the notations “amplifier 1” and “amplifier 2” in the drawing represent the first amplifier 130 and the second amplifier 132, respectively.

The fourth laser oscillator LO4 outputs a seed light beam SL in a first polarization direction at an ultraviolet wavelength of 150 nm to 380 nm. The fourth laser oscillator LO4 may be a solid laser that can operate in a high repetition mode and outputs the seed light beam SL at a wavelength of a KrF laser or an ArF laser. The spectral linewidth of the seed light beam SL output from the fourth laser oscillator LO4 may be narrowed to 1 pm or less. The solid laser may be, for example, a third overtone (a wavelength of 248.4 nm) Ti sapphire laser with a wavelength of 745.2 nm or a fourth overtone (a wavelength of 193.4 nm) of a Ti sapphire laser with a wavelength of 773.6 nm.

The beam splitter BS splits a seed light beam SL output from the fourth laser oscillator LO4 into two seed light beams SL. The split ratio between the amount of transmitted light and the amount of reflected light at the beam splitter BS may be 1:1.

Each of the first amplifier 130 and the second amplifier 132 amplifies the seed light beams SL split by the beam splitter BS. Each of the first amplifier 130 and the second amplifier 132 may be, for example, an excimer amplifier of discharge-excitation type and may include a Fabry-Perot resonator, a ring resonator, or a multi-pass amplifier. The multi-pass amplifier is configured to cause a beam passing through the amplifier by a plurality of reflective mirrors and cause the beam to turn back to pass through the same amplifier a plurality of times.

The repetition frequency of the first amplifier 130 and the second amplifier 132 is the same, and the repetition frequency of the fourth laser oscillator LO4 is twice the repetition frequency of the first amplifier 130 and the second amplifier 132. For example, the repetition frequency of each of the first amplifier 130 and the second amplifier 132 is 6 kHz, and the repetition frequency of the fourth laser oscillator LO4 is 12 kHz.

The Faraday rotator 140 is configured of a Faraday material 144 and a permanent magnet 146 that causes the polarization direction of the pulsed laser light PL to rotate by 45 degrees counterclockwise when viewed in a direction in which the pulsed laser light PL travels. The Faraday material 144 may be, for example, CaF₂, MgF₂, or synthetic quartz. Instead of the Faraday rotator 140, a wavelength plate that causes the polarization direction of the pulsed laser light PL to rotate by 45 degrees counterclockwise may be adopted. The other configurations are similar to those in FIG. 4.

The Faraday rotator 140 is an example of the “third Faraday rotator” in the present disclosure. The Faraday material 144 is an example of the “fourth Faraday material” in the present disclosure, and the permanent magnet 146 is an example of the “third permanent magnet” in the present disclosure.

### 5.2 Operation

In regard to the seed light beam SL in the first polarization direction output from the fourth laser oscillator LO4, 50% thereof is transmitted through the beam splitter BS and is then incident on the first amplifier 130, while the other 50% is reflected and is then incident on the second amplifier 132.

The laser processor 222 causes the first amplifier 130 and the second amplifier 132 to alternately operate for each pulse of the seed light beam SL. When the first amplifier 130 is caused to operate, the first amplifier 130 amplifies one of the seed light beams SL split by the beam splitter BS and outputs first pulsed laser light PL1.

When the second amplifier 132 is caused to operate, the second amplifier 132 amplifies the other of the seed light beams SL split by the beam splitter BS and outputs second pulsed laser light PL2.

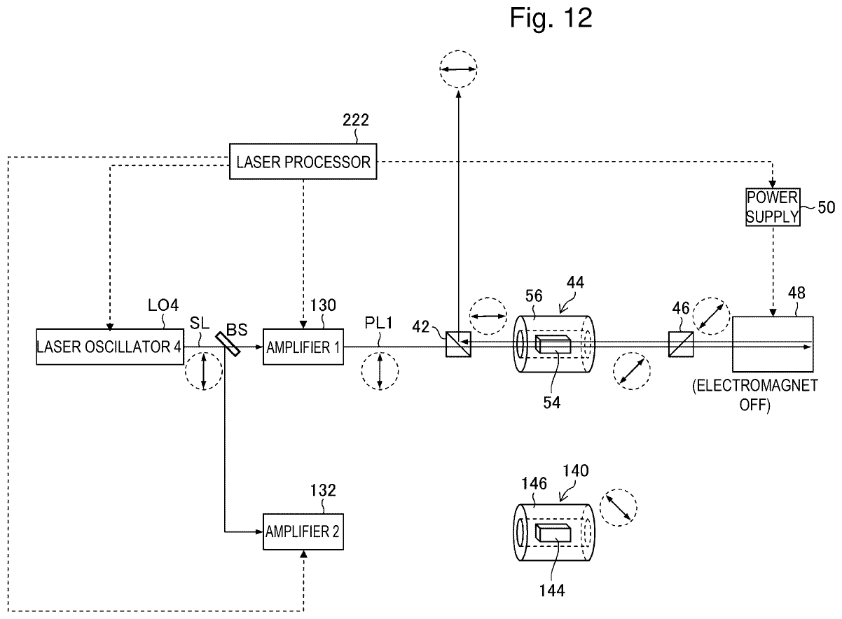

FIG. 12 illustrates how the first pulsed laser light PL1 output from the first amplifier 130 propagates. The propagation of the first pulsed laser light PL1 output from the first amplifier 130 is similar to that in the first embodiment.

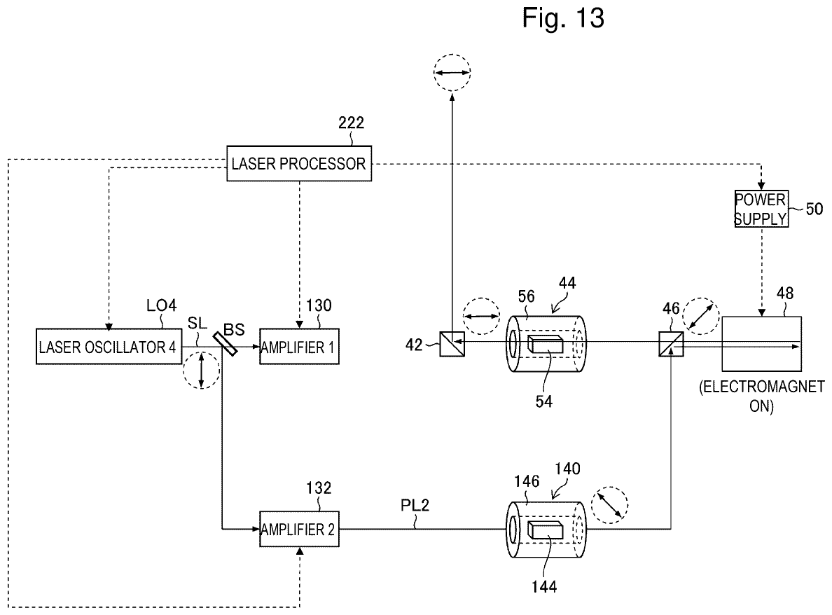

FIG. 13 illustrates how the second pulsed laser light PL2 output from the second amplifier 132 propagates. The propagation of the second pulsed laser light PL2 output from the second amplifier 132 is similar to that in the second embodiment. The laser processor 222 turns off the electromagnet when the first pulsed laser light PL1 is incident on the multi-pass Faraday mirror 48, and turns on the electromagnet when the second pulsed laser light PL2 is incident on the multi-pass Faraday mirror 48.

As a result, the first pulsed laser light PL1 in the first polarization direction and the second pulsed laser light PL2 in the second polarization direction are coupled by the beam combiner 40 such that they propagate in a common direction. The coupled first pulsed laser light PL1 and second pulsed laser light PL2 in the fourth polarization direction are output alternately from the laser system 10C.

### 5.3 Effect

With the laser system 10C according to the third embodiment, the same effect as that in the first embodiment is obtained. With the laser system 10C, fluctuations in wavelength and spectral linewidth of the pulsed laser light output from the laser system 10C can be reduced because there is a single fourth laser oscillator LO4.

### 6. Concerning Electronic Device Manufacturing Method

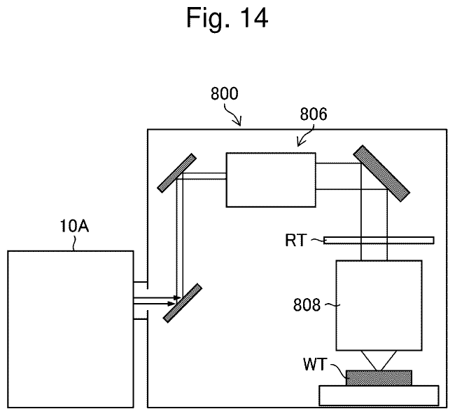

FIG. 14 schematically illustrates a configuration of an exposure apparatus 800. The exposure apparatus 800 includes an illumination optical system 806 and a projection optical system 808. The laser system 10A generates laser light and outputs the laser light to the exposure apparatus 800. The illumination optical system 806 illuminates, with the laser light incident thereon from the laser system 10A, a reticle pattern of a reticle, which is not illustrated, disposed on a reticle stage RT. The projection optical system 808 projects the laser light transmitted through the reticle in a reduced size and forms an image thereof on a workpiece, which is not illustrated, disposed on a workpiece table WT. The workpiece is a photosensitive substrate such as a semiconductor wafer with a photoresist applied thereto.

The exposure apparatus 800 causes the reticle stage RT and the workpiece table WT to move in parallel in synchronization to expose the workpiece to the laser light reflecting the reticle pattern. The reticle pattern is transferred to the semiconductor wafer through the exposure process as described above, and then a plurality of processes are performed to thereby manufacture a semiconductor device. The semiconductor device is an example of the “electronic device” in the present disclosure. The configuration is not limited to the one using the laser system 10A, and the laser system 10B, 10C, or the like may be used.

### 7. Others

The description above is intended to be illustrative and the present disclosure is not limited thereto. Therefore, it would be obvious for those skilled in the art that various modifications to the embodiments of the present disclosure would be possible without departing from the spirit and the scope of the appended claims. Further, it would be also obvious for those skilled in the art that the embodiments of the present disclosure would be used in combination.

The terms used throughout the present specification and the claims should be interpreted as “non-limiting” terms unless expressly stated otherwise. For example, terms such as “comprise”, “include”, “have”, and “contain” should not be interpreted to be exclusive of other structural elements. Further, indefinite articles “a/an” should be interpreted to mean “at least one” or “one or more”. Further, “at least one of A, B, and C” should be interpreted to mean any of “A”, “B”, “C”, “A+B”, “A+C”, “B+C”, and “A+B+C”. In addition, combinations of them with other than “A”, “B”, and “C” should also be construed as being included.

What is claimed is:

1. A laser system comprising:
a laser oscillator system configured to output first pulsed laser light in a first polarization direction and second pulsed laser light in a second polarization direction, which is obtained by rotating the first polarization direction by 45 degrees in a first rotation direction;
a beam combiner configured to couple the first pulsed laser light and the second pulsed laser light such that the first pulsed laser light and the second pulsed laser light are caused to propagate in a common direction, the beam combiner including
a first polarizer that transmits the first pulsed laser light,
a first Faraday rotator that rotates a polarization direction of the first pulsed laser light transmitted through the first polarizer by 45 degrees in a second rotation direction that is a direction opposite to the first rotation direction,
a second polarizer that transmits the first pulsed laser light transmitted through the first Faraday rotator and reflects the second pulsed laser light, and
a multi-pass Faraday mirror that reflects the first pulsed laser light transmitted through the second polarizer and the second pulsed laser light reflected by the second polarizer towards the second polarizer,
the multi-pass Faraday mirror including a first Faraday material through which the first pulsed laser light and the second pulsed laser light are transmitted, an electromagnet that applies a magnetic field to the first Faraday material, and a plurality of reflective mirrors that cause the first pulsed laser light and the second pulsed laser light transmitted through the first Faraday material to turn back toward the first Faraday material;
a power supply configured to cause a current to flow to the electromagnet; and
a processor configured to control the current flowing to the electromagnet via the power supply such that no current is caused to flow to the electromagnet when the first pulsed laser light is transmitted through the first Faraday material while a current is caused to flow to the electromagnet to rotate a polarization direction of the second pulsed laser light by 90 degrees when the second pulsed laser light is transmitted through the first Faraday material.

2. The laser system according to claim 1, wherein
the processor causes the laser oscillator system to alternately output the first pulsed laser light and the second pulsed laser light.

3. The laser system according to claim 1, wherein
the first Faraday material is calcium fluoride, magnesium fluoride, or synthetic quartz.

4. The laser system according to claim 1, wherein
the first Faraday rotator includes a second Faraday material and a first permanent magnet that applies a magnetic field to the second Faraday material, and
the second Faraday material is calcium fluoride, magnesium fluoride, or synthetic quartz.

5. The laser system according to claim 1, wherein
the multi-pass Faraday mirror includes four high reflective mirrors that are the plurality of reflective mirrors that reflect the first pulsed laser light and the second pulsed laser light transmitted through the first Faraday material such that the first pulsed laser light and the second pulsed laser light that have been incident pass through the first Faraday material eight times and are then caused to outgo toward the second polarizer.

6. The laser system according to claim 1, wherein
the first Faraday material includes reflective coatings as the plurality of reflective mirrors that reflect the first pulsed laser light and the second pulsed laser light on parts of a surface of the first Faraday material on which the first pulsed laser light and the second pulsed laser light are incident and a surface from which the first pulsed laser light and the second pulsed laser light are output such that the first pulsed laser light and the second pulsed laser light that have been incident pass through the first Faraday material a plurality of times and are then output toward the second polarizer.

7. The laser system according to claim 1, wherein
the laser oscillator system includes a first laser oscillator configured to output the first pulsed laser light in the first polarization direction, and
a second laser oscillator configured to output the second pulsed laser light in the second polarization direction.

8. The laser system according to claim 1, wherein
the laser oscillator system includes a first laser oscillator configured to output the first pulsed laser light in the first polarization direction,
a third laser oscillator configured to output the second pulsed laser light in the first polarization direction, and
a second Faraday rotator that rotates a polarization direction of the first pulsed laser light output from the third laser oscillator by 45 degrees in the first rotation direction, and
the laser oscillator system causes the second Faraday rotator to output the second pulsed laser light in the second polarization direction.

9. The laser system according to claim 8, wherein
the second Faraday rotator includes a third Faraday material and a second permanent magnet that applies a magnetic field to the third Faraday material, and
the third Faraday material is calcium fluoride, magnesium fluoride, or synthetic quartz.

10. The laser system according to claim 1, wherein
the laser oscillator system includes
a fourth laser oscillator configured to output a seed light beam in the first polarization direction,
a beam splitter that splits the seed light beam,
a first amplifier configured to amplify one of seed light beams split by the beam split and output the first pulsed laser light,
a second amplifier configured to amplify the other one of the seed light beams split by the beam splitter and output the second pulsed laser light, and
a third Faraday rotator that rotates a polarization direction of the second pulsed laser light output from the second amplifier by 45 degrees in the first rotation direction.

11. The laser system according to claim 10, wherein
the third Faraday rotator includes a fourth Faraday material and a third permanent magnet that applies a magnetic field to the fourth Faraday material, and
the fourth Faraday material is calcium fluoride, magnesium fluoride, or synthetic quartz.

12. The laser system according to claim 10, wherein
the fourth laser oscillator is a solid laser configured to output the seed light beam of a wavelength of a KrF excimer laser or an ArF excimer laser.

13. The laser system according to claim 10, wherein
each of the first amplifier and the second amplifier includes a Fabry-Perot resonator, a ring resonator, or a multi-pass amplifier.

14. The laser system according to claim 10, wherein
the processor causes the first amplifier and the second amplifier to alternately operate for each pulse of the seed light beam output from the fourth laser oscillator.

15. The laser system according to claim 1, wherein
wavelengths of the first pulsed laser light and the second pulsed laser light are ultraviolet wavelengths.

16. The laser system according to claim 1, wherein
the first pulsed laser light and the second pulsed laser light coupled and output by the beam combiner have a same polarization direction.

17. An electronic device manufacturing method comprising:
generating laser light with a laser system, the laser system including
a laser oscillator system configured to output first pulsed laser light in a first polarization direction and second pulsed laser light in a second polarization direction, which is obtained by rotating the first polarization direction by 45 degrees in a first rotation direction,
a beam combiner configured to couple the first pulsed laser light and the second pulsed laser light such that the first pulsed laser light and the second pulsed laser light are caused to propagate in a common direction, the beam combiner including
a first polarizer that transmits the first pulsed laser light,
a first Faraday rotator that rotates a polarization direction of the first pulsed laser light transmitted through the first polarizer by 45 degrees in a second rotation direction that is a direction opposite to the first rotation direction,
a second polarizer that transmits the first pulsed laser light transmitted through the first Faraday rotator and reflects the second pulsed laser light, and
a multi-pass Faraday mirror that reflects the first pulsed laser light transmitted through the second polarizer and the second pulsed laser light reflected by the second polarizer towards the second polarizer,
the multi-pass Faraday mirror including a first Faraday material through which the first pulsed laser light and the second pulsed laser light are transmitted, an electromagnet that applies a magnetic field to the first Faraday material, and a plurality of reflective mirrors that cause the first pulsed laser light and the second pulsed laser light transmitted through the first Faraday material to turn back toward the first Faraday material,
a power supply configured to cause a current to flow to the electromagnet, and
a processor configured to control the current flowing to the electromagnet via the power supply such that no current is caused to flow to the electromagnet when the first pulsed laser light is transmitted through the first Faraday material while a current is caused to flow to the electromagnet to rotate a polarization direction of the second pulsed laser light by 90 degrees when the second pulsed laser light is transmitted through the first Faraday material;
outputting the laser light to an exposure apparatus; and
exposing a photosensitive substrate to the laser light within the exposure apparatus to manufacture an electronic device.
